(19) United States
(12) Patent Application Publication
(10) Pub. No.: US 2018/0347030 A1
(43) Pub. Date: Dec. 6, 2018

(54) HIGH FREQUENCY INDUCTED EVAPORATION SOURCE DEVICE

(71) Applicant: Wuhan China Star Optoelectronics Technology Co., Ltd., Wuhan City (CN)

(72) Inventor: Junying Mu, Wuhan City (CN)

(21) Appl. No.: 15/506,243

(22) PCT Filed: Feb. 17, 2017
(86) PCT No.: PCT/CN2017/073879

§ 371 Date: Feb. 24, 2017

(30) Foreign Application Priority Data
Dec. 28, 2016 (CN) 201611233960.8

(51) Int. Cl. C23C 14/26

(52) U.S. Cl. CPC C23C 14/26

(57) ABSTRACT

Provided is a high frequency inducted evaporation source device, comprising an inner crucible for carrying an evaporation material, an induction coil set on periphery of the inner crucible and a radio frequency generator connected with the induction coil and a radio frequency induction heating component located in the inner crucible; the induction coil used for receiving an alternating current of the radio frequency generator to generate an induced magnetic field; the radio frequency induction heating component comprising an induction inner core body of generating an induction current in an induced magnetic field of the induction coil and generating heat to heat the evaporation material. The present invention can effectively disperse the heating zone of the evaporation material to effectively avoid the issues that the local heating rate of evaporation material is not uniform, and the evaporation material near the inner crucible wall is locally overheated and cracked.

### FIELD OF THE INVENTION

The present invention relates to a display technology field, and more particularly to a high frequency inducted evaporation source device.

### BACKGROUND OF THE INVENTION

The OLED (Organic Light-Emitting Diode) display, which is also named as the Organic light emitting display, is a new flat panel display device. Because it possesses advantages of simple manufacture process, low cost, low power consumption, high light emitting brightness, wide operating temperature range, thin volume, fast response speed, and being easy to achieve the color display and the large screen display, and being easy to achieve the match with the integrated circuit driver, and being easy to achieve the flexible display. Therefore, it has the broad application prospects. At present, the OLED manufacture technology of achieving mass production is using the vacuum evaporation to manufacture the OLED material thin film.

The vacuum evaporation method is to heat the raw material for forming the thin film in the evaporation container in a vacuum chamber to make the atoms or molecules be gasified and escape from the surface to form a vapor steam, which is incident to the surface of the substrate to form a solid thin film. The evaporation source is a key component of the evaporation device. According to the shape of the evaporation source, these can be a point evaporation source, a line evaporation source or a plane evaporation source. According to the heating manner of the evaporation source, the evaporation sources can be categorized to be a resistance heating evaporation source, an electron beam heating evaporation source, a High Frequency Induced Cell (HFIC), and a laser beam heating evaporation source. The resistance heating evaporation source is to use high melting point metal, such as tantalum (Ta) to be an evaporation source with a proper shape, such as a heating wire to be applied with an direct current for directly heating and evaporating the evaporation material and to be applied for the material of the evaporation coating, of which the melting point is not very high. Because the apparatus structure is simple, and the cost is cheap, and it is reliable, and massively applied in the actual production at present. The HFIC method is to position the crucible carrying the evaporation material in the center of the metal induction coil of copper (Cu), and the induction coil is applied with a high frequency current to generate a strong eddy current loss and hysteresis loss under the induction of the high frequency band magnetic field to heat up the evaporation material until it evaporates. The property of the HFIC is the high evaporation rate, and the evaporation material can generate the heat as the evaporation material is metal, and is applied for the application of the special material. Thus, the HFIC is an important supplement of a resistance heating evaporation source.

As shown in FIG. 1, which is a high frequency inducted evaporation source device according to prior art, comprising an outer crucible 10, an inner crucible 20 located inside the outer crucible 10, an induction coil 30 set on periphery of the outer crucible 10, a thermal insulator 40 located between the induction coil 30 and the outer crucible 10, a thermal couple 50 located below the outer crucible 10 and a radio frequency generator 60 connected to the induction coil 30, wherein the outer crucible 10 uses the material with conductivity and high temperature resistance, and the inner crucible 20 needs to use the high temperature resistant and chemically stable material to prevent the reaction with the evaporation material in the heating process. During use, the induction coil 30 receives an alternating current from the radio frequency generator 60 to generate an induced magnetic field. The outer crucible 10 generates an induction current under the induced magnetic field to generate heat for heating the inner crucible 20 and the evaporation material positioned inside the inner crucible 20. Besides, the high frequency inducted evaporation source device is further configured with a Process Cooling Water (PCW) passage for cooling the induction coil 30 during use.

With the increase of the substrate dimension, the dimension of the inner crucible 20 is also increased along with. The foregoing high frequency inducted evaporation source device has the following shortcomings during use:

1, the evaporation material away from the wall of the inner crucible 20 is hard to be fully heated, and the nonuniform local heating rate occurs;

2, the evaporation material near the wall of the inner crucible 20 is overheated and cracked.

### SUMMARY OF THE INVENTION

An objective of the present invention is to provide a high frequency inducted evaporation source device. By configuring the radio frequency induction heating component having conductivity inside the inner crucible to heat the evaporation material to effectively avoid the occurrence that the local heating rate of evaporation material is not uniform, and the local overheat and crack.

For realizing the aforesaid objective, the present invention provides a high frequency inducted evaporation source device, comprising an inner crucible for carrying an evaporation material, an induction coil set on periphery of the inner crucible and a radio frequency generator connected with the induction coil and a radio frequency induction heating component located in the inner crucible;

the induction coil used for receiving an alternating current generated by the radio frequency generator to generate an induced magnetic field; the radio frequency induction heating component comprising an induction inner core body, and the induction inner core body having conductivity to generate an induction current in an induced magnetic field of the induction coil and generating heat to heat the evaporation material.

The radio frequency induction heating component further comprises a heat conduction layer covering an outer surface of the induction inner core body;

a material of the induction inner core body is tantalum or graphite; a material of the heat conduction layer is alumina, boron nitride or titanium.

The radio frequency induction heating component as a whole is a solid structure or a hollow structure.

The radio frequency induction heating component as a whole is cylindrical or platelike.

The high frequency inducted evaporation source device further comprises an outer crucible between the inner crucible and the induction coil, and the inner crucible is inside the outer crucible.

The high frequency inducted evaporation source device further comprises a thermal insulation layer located between the induction coil and the outer crucible.

A material of the outer crucible is tantalum or graphite; a material of the inner crucible is alumina or boron nitride.

The high frequency inducted evaporation source device further comprises a thermocouple located below the outer crucible.

A material of the induction coil is copper.

As the high frequency inducted evaporation source device is during use, the induction coil is cooled by process cooling water, in which the induction coil is cooled by configuring a cooling water passage on an outside thereof and passing the process cooling water into the cooling water passage; or

the induction coil is a spirally wound hollow tube, in which the induction coil is cooled by passing the process cooling water into the induction coil.

The present invention further provides a high frequency inducted evaporation source device, comprising an inner crucible for carrying an evaporation material, an induction coil set on periphery of the inner crucible and a radio frequency generator connected with the induction coil and a radio frequency induction heating component located in the inner crucible;

the induction coil used for receiving an alternating current generated by the radio frequency generator to generate an induced magnetic field;

the radio frequency induction heating component comprising an induction inner core body, and the induction inner core body having conductivity to generate an induction current in an induced magnetic field of the induction coil and generating heat to heat the evaporation material;

the high frequency inducted evaporation source device further comprising an outer crucible between the inner crucible and the induction coil, and the inner crucible is inside the outer crucible;

the high frequency inducted evaporation source device further comprising a thermal insulation layer located between the induction coil and the outer crucible;

the high frequency inducted evaporation source device further comprising a thermocouple located below the outer crucible.

The benefits of the present invention are: the present invention provides a high frequency inducted evaporation source device, comprising an inner crucible for carrying an evaporation material, an induction coil set on periphery of the inner crucible and a radio frequency generator connected with the induction coil and a radio frequency induction heating component located in the inner crucible; the induction coil used for receiving an alternating current generated by the radio frequency generator to generate an induced magnetic field; the radio frequency induction heating component comprising an induction inner core body, and the induction inner core body generating an induction current in an induced magnetic field of the induction coil and generating heat to heat the evaporation material. In comparison with the high frequency inducted evaporation source device of prior art, the present invention can effectively disperse the heating zone of the evaporation material in the inner crucible to effectively avoid the issues that the local heating rate of evaporation material is not uniform, and the evaporation material near the inner crucible wall is locally overheated and cracked.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a diagram of a high frequency inducted evaporation source device according to prior art;

FIG. 2 is a diagram of a high frequency inducted evaporation source device according to the present invention;

FIG. 3 is a top view diagram as the high frequency inducted evaporation source device according to the present invention is a point evaporation source device;

FIG. 4 is a top view diagram as the high frequency inducted evaporation source device according to the present invention is a line evaporation source device;

FIG. 5A is a local profile of the first embodiment of an induction coil of the high frequency inducted evaporation source device according to the present invention;

FIG. 5B is a local profile of the second embodiment of an induction coil of the high frequency inducted evaporation source device according to the present invention.

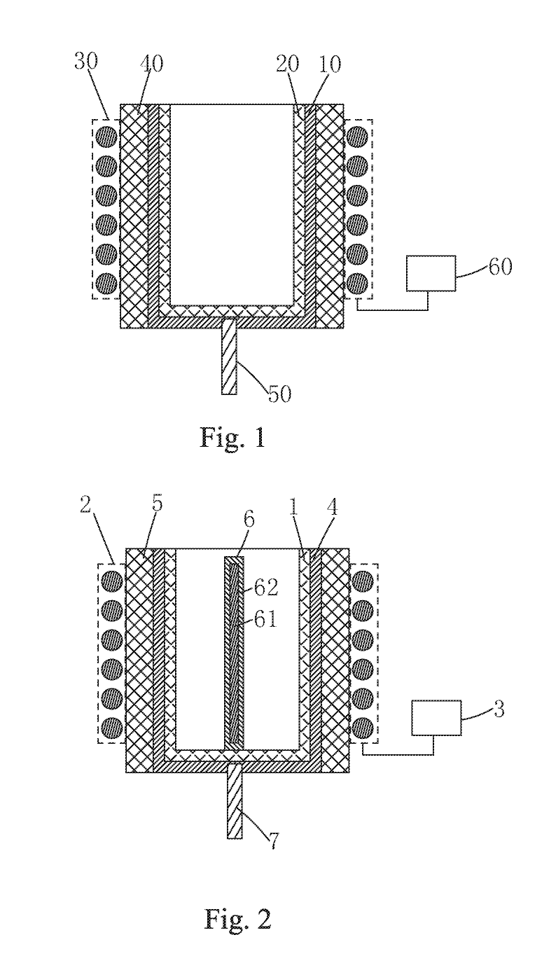

### DETAILED DESCRIPTION OF PREFERRED EMBODIMENTS

For better explaining the technical solution and the effect of the present invention, the present invention will be further described in detail with the accompanying drawings and the specific embodiments.

Please refer to FIG. 2. The present invention provides a high frequency inducted evaporation source device, comprising an inner crucible 1 for carrying an evaporation material, an induction coil 2 set on periphery of the inner crucible 1 and a radio frequency generator 3 connected with the induction coil 2 and a radio frequency induction heating component (High Frequency Induced Heater) 6 located in the inner crucible 1;

the induction coil 2 used for receiving an alternating current generated by the radio frequency generator 3 to generate an induced magnetic field; the radio frequency induction heating component 6 comprising an induction inner core body 61, and the induction inner core body 61 having conductivity to generate an induction current in an induced magnetic field of the induction coil 2 and generating heat to heat the evaporation material.

The high frequency inducted evaporation source device of the present invention configures the radio frequency induction heating component 6 in the inner crucible 1 to heat the evaporation material. In comparison with prior art that the high frequency inducted evaporation source device only conduct the heat through the inner crucible wall to heat the evaporation material, the present invention can effectively disperse the heating zone of the evaporation material in the inner crucible 1 to effectively avoid the issues that the local heating rate of evaporation material is not uniform, and the evaporation material near the inner crucible wall is locally overheated and cracked.

Specifically, for avoiding that the induction inner core body 61 of the radio frequency induction heating component 6 directly contacts with the evaporation material in the heating process to cause pollution to the evaporation material, the radio frequency induction heating component 6 further comprises a heat conduction layer 62 covering an outer surface of the induction inner core body 61.

A material of the induction inner core body 61 is a material, which is resistant to high temperature and has conductivity, such as tantalum or graphite; a material of the heat conduction layer is a high temperature resistant, chemically stable material, such as alumina (Al2O3), boron nitride (BN) or titanium (Ti).

Specifically, the radio frequency induction heating component 6 as a whole can be a solid structure, or can be a hollow structure.

Specifically, a shape of the radio frequency induction heating component 6 is designed according to the entire appearance of the high frequency inducted evaporation source device, and can be applied in a point evaporation device, a line evaporation device or a plane evaporation device.

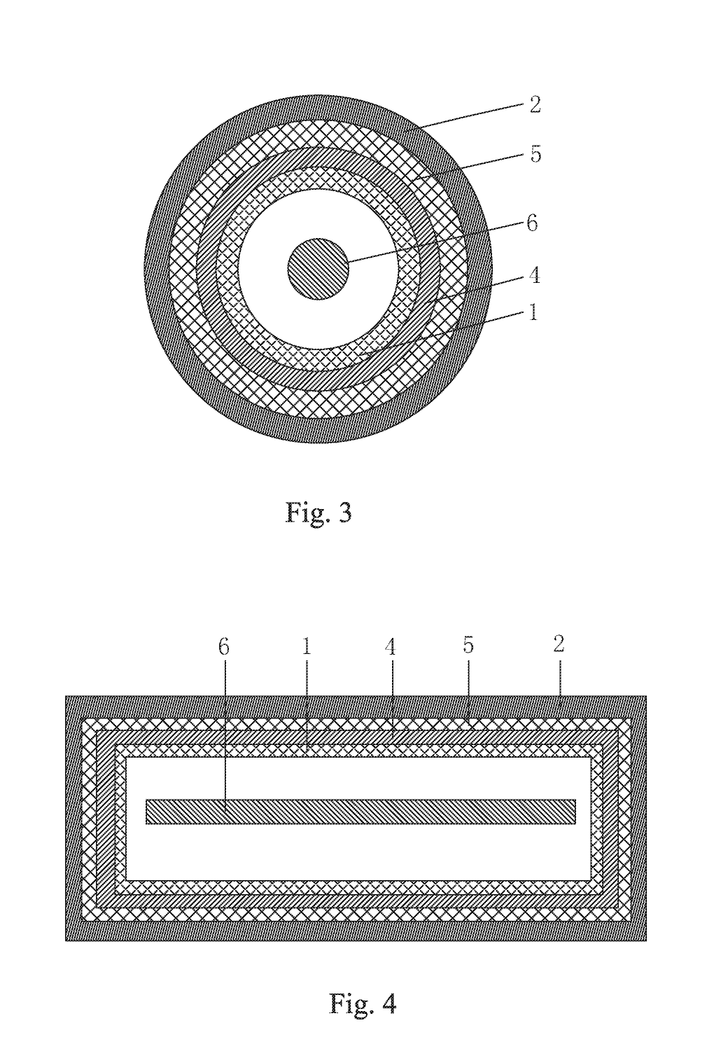

For instance, as shown in FIG. 3, the high frequency inducted evaporation source device of the present invention is a point evaporation device. The horizontal section of the inner crucible 1 appears to be a circle, and the radio frequency induction heating component 6 appears to be cylindrical and is located inside the inner crucible 1. Certainly, the radio frequency induction heating component 6 also can be other shapes of being adapted for the shape of the inner crucible 1.

For another example, as shown in FIG. 4, the high frequency inducted evaporation source device of the present invention is a line evaporation device. The horizontal section of the inner crucible 1 appears to be a rectangle, and the radio frequency induction heating component 6 appears to be platelike. Certainly, the radio frequency induction heating component 6 also can be other shapes of being adapted for the shape of the inner crucible 1.

Specifically, the high frequency inducted evaporation source device of the present invention further comprises an outer crucible 4 between the inner crucible 1 and the induction coil 2, a thermal insulation layer 5 located between the induction coil 2 and the outer crucible 4 and a thermocouple 7 located below the outer crucible 4, and the inner crucible 1 is inside the outer crucible 4.

Specifically, a material of the outer crucible 4 is a material, which is resistant to high temperature and has conductivity, such as tantalum or graphite; a material of the inner crucible 1 is a high temperature resistant, chemically stable material, such as alumina; material of the heat conduction layer 5 is an insulation material, such as alumina to serve a function of insulation.

Specifically, as the high frequency inducted evaporation source device is during use, the radio frequency induction heating component 6 can heat the evaporation material with the outer crucible 4, together. Certainly, it also can independently heat the evaporation material.

Specifically, a material of the induction coil 2 is a metal material, such as copper.

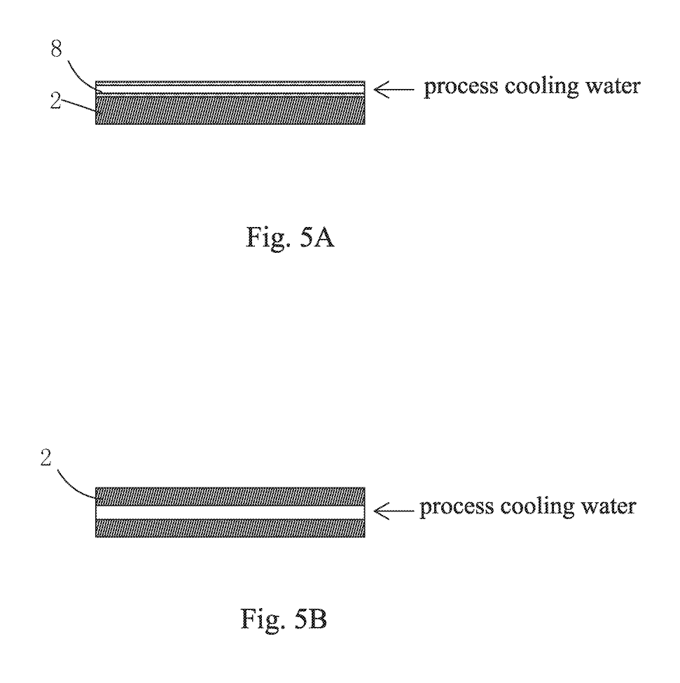

Specifically, during use, the induction coil 2 is cooled by process cooling water (PCW); specifically, referring to FIG. 5A, the induction coil 2 can be cooled by configuring a cooling water passage 8 on an outside of the induction coil 2 and passing the process cooling water into the cooling water passage 8; or,

please refer to FIG. 5B, the induction coil 2 itself is a spirally wound hollow tube, in which the induction coil 2 is cooled by passing the process cooling water into the induction coil 2.

In conclusion, the high frequency inducted evaporation source device provided by the present invention comprises an inner crucible for carrying an evaporation material, an induction coil set on periphery of the inner crucible and a radio frequency generator connected with the induction coil and a radio frequency induction heating component located in the inner crucible; the induction coil used for receiving an alternating current generated by the radio frequency generator to generate an induced magnetic field; the radio frequency induction heating component comprising an induction inner core body, and the induction inner core body generating an induction current in an induced magnetic field of the induction coil and generating heat to heat the evaporation material. In comparison with the high frequency inducted evaporation source device of prior art, the present invention can effectively disperse the heating zone of the evaporation material in the inner crucible to effectively avoid the issues that the local heating rate of evaporation material is not uniform, and the evaporation material near the inner crucible wall is locally overheated and cracked.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A high frequency inducted evaporation source device, comprising an inner crucible for carrying an evaporation material, an induction coil set on periphery of the inner crucible and a radio frequency generator connected with the induction coil and a radio frequency induction heating component located in the inner crucible;
the induction coil used for receiving an alternating current generated by the radio frequency generator to generate an induced magnetic field;
the radio frequency induction heating component comprising an induction inner core body, and the induction inner core body having conductivity to generate an induction current in an induced magnetic field of the induction coil and generating heat to heat the evaporation material.

2. The high frequency inducted evaporation source device according to claim 1, wherein the radio frequency induction heating component further comprises a heat conduction layer covering an outer surface of the induction inner core body;
a material of the induction inner core body is tantalum or graphite; a material of the heat conduction layer is alumina, boron nitride or titanium.

3. The high frequency inducted evaporation source device according to claim 2, wherein the radio frequency induction heating component as a whole is a solid structure or a hollow structure.

4. The high frequency inducted evaporation source device according to claim 2, wherein the radio frequency induction heating component as a whole is cylindrical or platelike.

5. The high frequency inducted evaporation source device according to claim 1, further comprising an outer crucible between the inner crucible and the induction coil, and the inner crucible is inside the outer crucible.

6. The high frequency inducted evaporation source device according to claim 5, further comprising a thermal insulation layer located between the induction coil and the outer crucible.

7. The high frequency inducted evaporation source device according to claim 6, wherein a material of the outer crucible is tantalum or graphite; a material of the inner crucible is alumina or boron nitride.

8. The high frequency inducted evaporation source device according to claim 5, further comprising a thermocouple located below the outer crucible.

9. The high frequency inducted evaporation source device according to claim 1, wherein a material of the induction coil is copper.

10. The high frequency inducted evaporation source device according to claim 1, wherein during use, the induction coil is cooled by process cooling water, in which the induction coil is cooled by configuring a cooling water passage on an outside thereof and passing the process cooling water into the cooling water passage; or
the induction coil is a spirally wound hollow tube, in which the induction coil is cooled by passing the process cooling water into the induction coil.

11. A high frequency inducted evaporation source device, comprising an inner crucible for carrying an evaporation material, an induction coil set on periphery of the inner crucible and a radio frequency generator connected with the induction coil and a radio frequency induction heating component located in the inner crucible;
the induction coil used for receiving an alternating current generated by the radio frequency generator to generate an induced magnetic field;
the radio frequency induction heating component comprising an induction inner core body, and the induction inner core body having conductivity to generate an induction current in an induced magnetic field of the induction coil and generating heat to heat the evaporation material;
the high frequency inducted evaporation source device further comprising an outer crucible between the inner crucible and the induction coil, and the inner crucible is inside the outer crucible;
the high frequency inducted evaporation source device further comprising a thermal insulation layer located between the induction coil and the outer crucible;
the high frequency inducted evaporation source device further comprising a thermocouple located below the outer crucible.

12. The high frequency inducted evaporation source device according to claim 11, wherein the radio frequency induction heating component further comprises a heat conduction layer covering an outer surface of the induction inner core body;
a material of the induction inner core body is tantalum or graphite; a material of the heat conduction layer is alumina, boron nitride or titanium.

13. The high frequency inducted evaporation source device according to claim 12, wherein the radio frequency induction heating component as a whole is a solid structure or a hollow structure.

14. The high frequency inducted evaporation source device according to claim 12, wherein the radio frequency induction heating component as a whole is cylindrical or platelike.

15. The high frequency inducted evaporation source device according to claim 11, wherein a material of the outer crucible is tantalum or graphite; a material of the inner crucible is alumina or boron nitride.

16. The high frequency inducted evaporation source device according to claim 11, wherein a material of the induction coil is copper.

17. The high frequency inducted evaporation source device according to claim 11, wherein during use, the induction coil is cooled by process cooling water, in which the induction coil is cooled by configuring a cooling water passage on an outside thereof and passing the process cooling water into the cooling water passage; or
the induction coil is a spirally wound hollow tube, in which the induction coil is cooled by passing the process cooling water into the induction coil.
